(19) United States
(12) Patent Application Publication
(10) Pub. No.: US 2025/0243583 A1
(43) Pub. Date: Jul. 31, 2025

(54) DEGAS SYSTEM USING INERT PURGE GAS AT CONTROLLED PRESSURE FOR A LIQUID DELIVERY SYSTEM OF A SUBSTRATE PROCESSING SYSTEM

(71) Applicant: LAM RESEARCH CORPORATION, Fremont, CA (US)

(72) Inventors: Brian RATLIFF, Hillsboro, OR (US); Colin F. Smith, Hall Moon Bay, CA (US)

(21) Appl. No.: 18/704,173

(22) PCT Filed: Oct. 31, 2022
(86) PCT No.: PCT/US2022/048454

§ 371 Date: Apr. 24, 2024

Related U.S. Application Data
(60) Provisional application No. 63/274,440, filed on Nov. 1, 2021.

(51) Int. Cl. C23C 16/455; C23C 16/44

(52) U.S. Cl. CPC C23C 16/45557; C23C 16/4412; C23C 16/45561

(57) ABSTRACT

A degas system includes a housing including a liquid inlet. a gas inlet. a liquid outlet. and a gas outlet. A tube is configured to receive a liquid including gas bubbles. The tube includes a plurality of loops. a first end fluidly connected to the liquid inlet of the housing. and a second end fluidly connected to the liquid outlet of the housing. The tube is gas permeable and liquid impermeable. A gas supply system is configured to supply gas to the gas inlet of the housing. A first conduit and a first restricted orifice are configured to fluidly connect the gas outlet of the housing to an exhaust system.

### CROSS-REFERENCE TO RELATED APPLICATIONS

This application claims the benefit of U.S. Provisional Application No. 63/274,440, filed on Nov. 1, 2021. The entire disclosure of the application referenced above is incorporated herein by reference.

### FIELD

The present disclosure relates to degas systems, and more particularly to a degas system for a liquid delivery system of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform deposition, etching and/or other treatment of substrates such as semiconductor wafers. A substrate may be arranged on a pedestal in a processing chamber. During deposition, a deposition gas mixture including one or more precursors is supplied to the processing chamber. In some applications, plasma may be struck in the processing chamber to promote chemical reactions.

When depositing film on substrates, gaseous or liquid precursors are delivered to the processing chamber. If liquid precursor is used, the liquid is degassed, metered and vaporized in a vaporizer. Carrier gas is used to entrain the vapor and deliver it to the processing chamber. Liquid delivery systems need to deliver the liquid to the vaporizer at a uniform pressure and/or a predetermined flow rate. The liquid should be free of particle impurities and/or gas bubbles.

Some liquid delivery systems include pumps that deliver the liquid. However, the pumps include dynamic seals that degrade over time and introduce unwanted impurities into the pumped liquid. Pump-based liquid delivery systems may not have uniform pressure due to variable pumping forces that are involved.

Instead of using a pump, some liquid delivery systems supply the liquid from a liquid container that is pressurized by an inert gas. When using this approach, some of the gas may dissolve into the liquid. Dissolved gas bubbles may cause problems at downstream locations. For example, at lower pressure conditions, the dissolved gas can be released by the liquid. Gas bubbles displace the liquid, which leads to inconsistent flow rates. Gas bubbles also change the thermal conductivity of the liquid. If a liquid mass flow controller is used, the gas bubbles may adversely affect operation of the liquid mass flow controller. If restricted orifices are used to control flow, the gas bubbles may also cause inaccuracies in metering of the liquid flow. As can be appreciated, variations in the liquid flow rate cause substrate non-uniformities such as variations in deposited thickness and/or quality.

### SUMMARY

A degas system includes a housing including a liquid inlet, a gas inlet, a liquid outlet, and a gas outlet. A tube is configured to receive a liquid including gas bubbles. The tube includes a plurality of loops, a first end fluidly connected to the liquid inlet of the housing, and a second end fluidly connected to the liquid outlet of the housing. The tube is gas permeable and liquid impermeable. A gas supply system is configured to supply gas to the gas inlet of the housing. A first conduit and a first restricted orifice are configured to fluidly connect the gas outlet of the housing to an exhaust system.

In other features, the gas supply system and the first restricted orifice are configured to create a first predetermined pressure in the housing that is greater than a second predetermined pressure of an exhaust system and less than a third predetermined pressure of the gas bubbles in the liquid.

In other features, the gas supply system includes a gas source. A second conduit and a second restricted orifice have an inlet fluidly connected to the gas source and an outlet fluidly connected to the gas inlet of the housing.

In other features, the gas source supplies gas at a first predetermined pressure. The second restricted orifice is sized to supply gas from the gas source at a predetermined flow rate. The first restricted orifice is configured to maintain pressure in the housing at a second predetermined pressure.

In other features, the first predetermined pressure is in a range from 40 to 70 psig. The second predetermined pressure in in a range from 20 to 40 Torr. The first restricted orifice has a size in a range from 300 to 550 micrometers. The second restricted orifice has a size in a range from 25 to 55 micrometers.

In other features, the gas supply system includes a gas source. A pressure regulator has an inlet fluidly connected to the gas source and an outlet fluidly connected to the gas inlet of the housing. The gas source supplies gas at a first predetermined pressure. The pressure regulator and the first restricted orifice are configured to maintain pressure in the housing at a second predetermined pressure.

In other features, the first predetermined pressure is in a range from 40 to 70 psig. The second predetermined pressure is in a range from 20 to 40 Torr.

In other features, the gas supply system includes a gas source. A gas mass flow controller has an inlet fluidly connected to the gas source. A valve has an inlet connected to an outlet of the gas mass flow controller and an outlet fluidly connected to the gas inlet of the housing.

In other features, the gas source supplies gas at a first predetermined pressure. The gas mass flow controller, the valve, and the first restricted orifice are configured to maintain pressure in the housing at a second predetermined pressure.

In other features, the first predetermined pressure is in a range from 40 to 70 psig. The second predetermined pressure is in a range from 20 to 40 Torr. The first restricted orifice has a size in a range from 300 to 550 micrometers. The gas bubbles comprise an inert gas. The liquid comprises an alkoxide of silicon. The gas comprises an inert gas.

A liquid delivery system for a substrate processing system includes the degas system, a liquid container to store the liquid, a gas source to pressurize the liquid container, and a conduit fluidly connecting a liquid outlet of the liquid container to the liquid inlet of the housing.

In other features, a liquid mass flow controller including an inlet fluidly connected to the liquid outlet of the housing. A vaporizer is fluidly connected to an outlet of the liquid mass flow controller.

In other features, the gas bubbles comprise helium (He). The liquid comprises tetraethyl orthosilicate (TEOS). The gas comprises argon (Ar).

In other features, the housing is sealed from atmosphere. The gas prevents the liquid from reacting with the atmosphere through the tube in the event of failure of the seal

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system including a liquid delivery system with a degas system;

FIG. 2 is a functional block diagram of an example of a substrate processing system including a liquid delivery system with a degas system according to the present disclosure;

FIG. 3 is a functional block diagram of another example of a substrate processing system including a liquid delivery system with a degas system according to the present disclosure; and

FIG. 4 is a functional block diagram of another example of a substrate processing system including a liquid delivery system with a degas system according to the present disclosure.

In the drawings, reference numbers may be reused to identify similar and/or identical elements.

### DETAILED DESCRIPTION

A liquid delivery system for a substrate processing system includes a degas system according to the present disclosure. The degas system is configured to remove gas bubbles from a liquid to be used in a substrate processing system.

The degas system includes a housing and a coiled tube arranged in the housing. The coiled tube provides a torturous path and is made of a material that is gas permeable and liquid impermeable. Permeability is a measure of ability of a porous material to allow fluids (e.g., gases and liquids) to pass through the porous material. The permeability of a medium is related to porosity, shapes of pores in the medium, and level of connectedness of the pores. The coiled tube is made of a material that allows gas to pass through the material but does not allow liquid to pass through the material. Therefore, the material is called gas permeable and liquid impermeable. An inert gas is supplied to the housing to control pressure therein and prevent back streaming of products from a foreline of an exhaust system into the housing of the degas system. The pressure in the housing of the degas system is kept above the pressure in the foreline using an outlet restricted orifice.

Inert gas can be supplied to the degas system in several different ways including using an inlet restricted orifice, a pressure regulator and/or a mass flow controller and a valve arranged at a gas inlet of the housing. When used, the inlet restricted orifice sets the mass flow rate of the gas. The outlet restricted orifice sets the degas pressure and maintains a controlled pressure inside the housing of the degas system to prevent back streaming. In general, a restriction orifice is a flow control device that offers a restriction to fluid flow so that a controlled or restricted flow is achieved. Due to the restriction, a pressure drop from upstream of the orifice to downstream is observed. A similar effect can be achieved using the pressure regulator and/or the mass flow controller and valve.

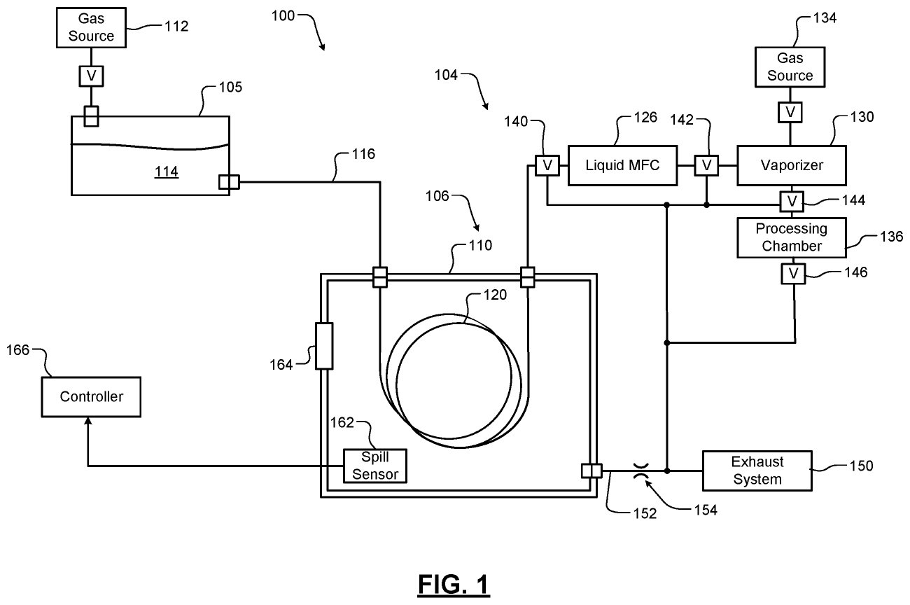

Referring now to FIG. 1, a substrate processing system 100 includes a liquid delivery system 104 and a degas system 106. The liquid delivery system 104 includes a liquid container 105 connected to a gas source 112. The gas source 112 increases pressure in the liquid container 105 and pushes liquid 114 stored in the liquid container 105 through a conduit 116 to the degas system 106.

The degas system 106 includes a housing 110 having a liquid inlet, a liquid outlet and a gas outlet. The degas system 106 includes a tube 120 having one end fluidly connected to the conduit 116 (via the liquid inlet) and another end fluidly connected to a liquid mass flow controller (MFC) 126 (via the liquid outlet). The tube 120 is gas permeable and liquid impermeable.

An outlet of the liquid MFC 126 is fluidly connected to a vaporizer 130, which may be connected to a gas source 134. The vaporizer 130 may include an atomizer (not shown) to vaporize the liquid and the gas source 134 supplies carrier gas to entrain the vapor. An outlet of the vaporizer 130 is connected to a processing chamber 136.

Valves 140, 142, 144 and 146 may be provided to selectively connect components of the substrate processing system 100 to the exhaust system 150 (for example during purging). In some examples, the gas sources 112 and 134 are fluidly connected by shut off valves (shown) and/or restricted orifices (not shown) to the liquid container 105 and/or the vaporizer 130.

The housing 110 is connected by a conduit 152 and a restricted orifice 154 to an exhaust system 150. In some examples, the restricted orifice 154 is sized to restrict the flow of the liquid in the event of a catastrophic failure. For example, a restrictor in the restricted orifice 154 is typically sized relatively small (e.g. less than or equal to about 150 um (e.g. 127 um (0.005″))).

In some examples, the valve 140 is fluidly connected to an outlet of the tube 120, an inlet of the liquid MFC 126 and the exhaust system 150. The valve 142 is fluidly connected to an outlet of the liquid MFC 126, an inlet of the vaporizer 130 and the exhaust system 150. The valve 144 is fluidly connected to an outlet of the vaporizer 130, an inlet of the processing chamber 136 and the exhaust system 150. The valve 146 is fluidly connected to the outlet of the processing chamber 136 and an inlet of the exhaust system 150. The valves 140, 142, 144, and 146 can be used during purging of the system.

In some examples, a spill sensor 162 is arranged in the housing 110 to sense failure of the tube 120. In some examples, the housing 110 may include a window 164 to allow viewing into the housing 110. A controller 166 may be used to control one or more components of the substrate processing system 100. For example, the controller 166 may be used to control system valves, the liquid MFC 126, the vaporizer 130, a recipe used by the processing chamber 136 and/or other system parameters.

In use, the gas source 112 provides pressure in the liquid container 105 to push the liquid 114 through the conduit 116 and the tube 120 to the liquid MFC 126. While the liquid flows through the tube 120, gas bubbles are removed since the tube 120 is gas permeable and the pressure is lower.

In some examples, the liquid container 105 is maintained at approximately the same pressure as the exhaust system 150 (e.g. around 0 Torr). As can be appreciated, the valves 140, 142, 144 and 146 are connected to the exhaust system 150 downstream from the restricted orifice 154. Variations in pressure may occur in the exhaust system 150. This may cause temporary differences in pressure in the liquid container 105 relative to the exhaust system. This may lead to vapor, reactants or other material (connected to the exhaust system 150 downstream from the restricted orifice 154) back streaming into the liquid container 105 and eventually moving back through the restricted orifice 154. This action may lead to clogging of the restricted orifice 154.

The restricted orifice 154 was originally used to protect against catastrophic failure of the tube 120 and has a relatively small restrictor. However, since the spill sensor 162 can be used to detect failure of the tube 120, the restricted orifice 154 is no longer needed for that function. Simply removing the restricted orifice 154 will increase back streaming of products from the exhaust system 150 into the liquid container 105. Some systems attempt to use a large separation distance between the foreline connection and the outlet of the housing of the degas system to prevent back streaming from the foreline. Simple separation, even using a non-straight length of narrow foreline tubing, is not sufficient to fully eliminate back streaming.

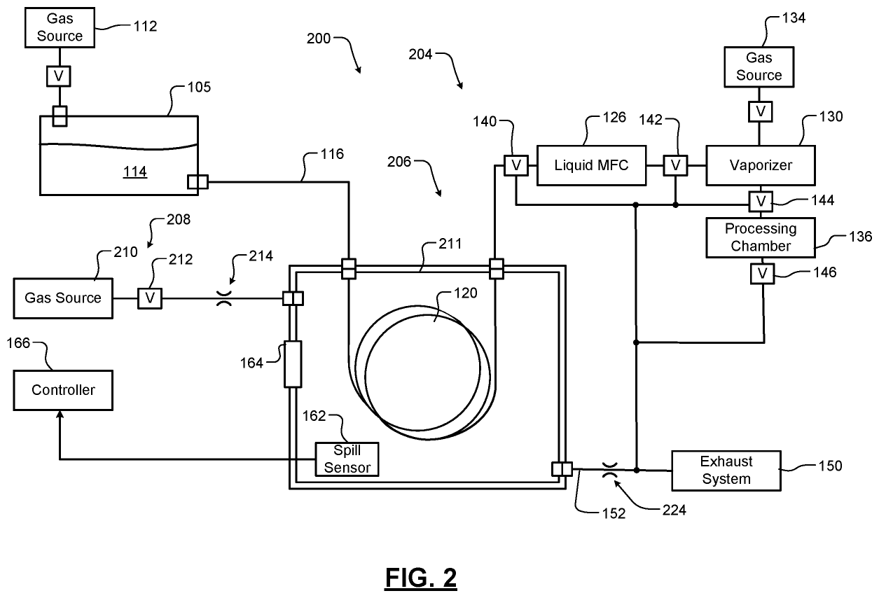

Referring now to FIG. 2, a substrate processing system 200 includes a liquid delivery system 204, a degas system 206 and a gas supply system 208. The degas system 206 includes a housing 211 including a liquid inlet, a liquid outlet, a gas inlet and a gas outlet. The gas supply system 208 includes a gas source 210 connected by a valve 212 and a restricted orifice 214 to the gas inlet of the housing 211. The gas outlet of the housing 211 is connected by a restricted orifices 224 to the exhaust system 150. In some examples, the restricted orifices 214 and 224 are sized to provide a predetermined pressure within the housing 211 to prevent back streaming of products from the exhaust system 150 into the housing 211.

In some examples, the predetermined pressure in the housing 211 is greater than the pressure in the exhaust system and less than the partial pressure of the gas bubbles in the liquid 114. In some examples, the predetermined pressure in the housing 211 is in a range from 15 to 45 Torr (e.g. 30 T) and the pressure in the exhaust system 150 is less than 10 Torr (e.g. around 0 Torr).

In some examples, the restricted orifice 224 is sized specifically to enforce a

predetermined pressure differential with respect to the exhaust system 150. For example, when the gas source 210 supplies argon (Ar) at 55 psig, the restricted orifice 214 includes a 40 um restrictor that provides 50 sccm Ar flow. The restricted orifice 224 includes a 430 um restrictor to control the predetermine pressure in the housing to around 30 T, although other restrictor sizes, pressures and flows may be used.

In some examples, the pressure of gas supplied by the gas source 210 is in a predetermined pressure range from 40 to 70 psig (e.g. 55 psig), although other pressures can be used. The predetermined pressure in the housing 211 is in a predetermined pressure range from 20 to 40 Torr (e.g. 30 T), although other pressures can be used. The inlet restricted orifice 214 has a size in a range from 25 to 55 micrometers (e.g. 40 um), although other sizes can be used. The outlet restricted orifice 154 has a size in a range from 300 to 550 micrometers (e.g. 430 um), although other sizes can be used.

In some examples, the gas source 112 supplies helium (He), the gas source 210 supplies argon (Ar) and the liquid comprises tetraethyl orthosilicate (TEOS), although other inert gases and/or liquids can be used. TEOS is an ethyl ester of orthosilicic acid, Si(OH)4. TEOS is an alkoxide of silicon. TEOS is a tetrahedral molecule prepared by alcoholysis of silicon tetrachloride. In some examples, the degas system eliminates He push gas in the form of bubbles in the TEOS liquid. The mechanism of the degassing is via diffusion through a membrane of the tube 120 via partial pressure differentials. Using argon at 30 Torr does not degrade the degassing performance of the degasser when using He push gas.

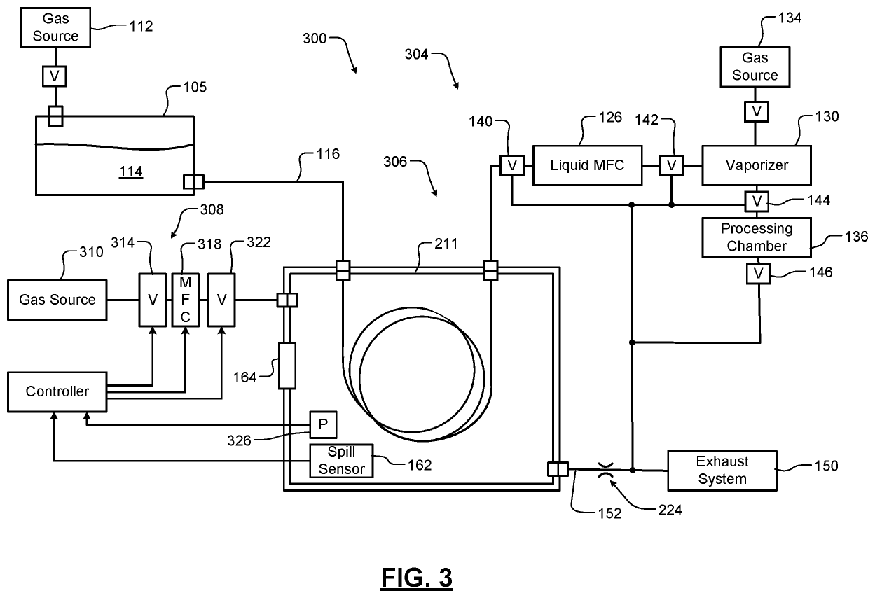

Referring now to FIG. 3, a substrate processing system 300 includes a liquid delivery system 304, a degas system 306 and a gas supply system 308. The gas supply system 308 includes a gas source 310 connected by a valve 314, a gas mass flow controller (MFC) 318 and a valve 322 to an inlet of the housing 211. An outlet of the housing 211 is connected by the conduit and the restricted orifice 224 to the exhaust system 150.

A pressure sensor 326 may be used to sense pressure in the housing 211. The controller 166 varies operation of the gas MFC 318, the valve 314 and/or the valve 322 to adjust a flow rate of the gas flowing to the gas inlet of the housing 211 to provide a predetermined pressure within the housing 211 and to prevent back streaming of products from the exhaust system 150. In some examples, the predetermined pressure in the housing 211 is greater than the pressure in the exhaust system 150 and less than the partial pressure of the gas bubbles in the liquid 114.

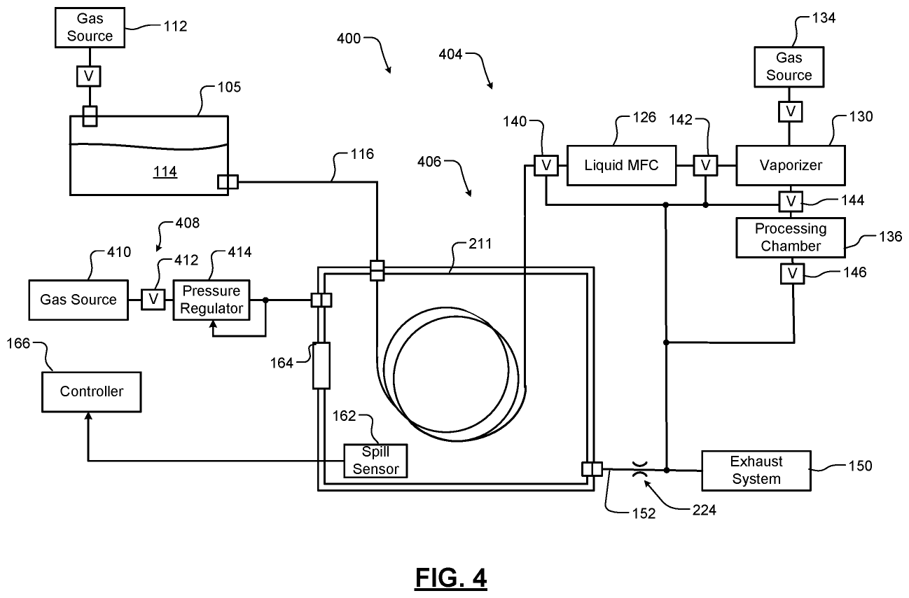

Referring now to FIG. 4, a substrate processing system 400 includes a liquid delivery system 404, a degas system 406 and a gas supply system 408. The gas supply system 408 includes a gas source 410 is connected by a valve 412 and a pressure regulator 414 to an inlet of the housing 211. An outlet of the housing 211 is connected by a restricted orifice 224 to the exhaust system 150. The pressure regulator 414 regulates pressure of gas flowing to the inlet of the housing 211 to provide a predetermined pressure within the housing 211 to prevent back streaming from the exhaust system 150. An outlet of the housing 211 is connected by the conduit 152 and the restricted orifice 224 to the exhaust system 150. In some examples, the predetermined pressure in the housing 211 is greater than the pressure in the exhaust system 150 and less than the partial pressure of the gas bubbles in the liquid 114.

In addition, the inert gas (also called purge gas) used in the degasser (the degas systems shown in FIGS. 2-4) protects reactive precursors (e.g., the liquid 114 supplied by the liquid container 105) from reacting with atmosphere through the membrane of tube 120. Specifically, the inert purge gas creates an inert atmosphere within the degasser. The pressure in the housing 211 is below the partial pressure of the inert purge gas and also above the pressure of the foreline (conduit 152) connecting the degasser to the exhaust system 150. The pressure in the housing 211 helps prevent back streaming of material from the foreline into the liquid container 105.

While the housing 211 is sealed against atmosphere, the purge function provided by the inert purge gas helps keep atmosphere from contaminating the liquid precursor if the seal fails. Without the inert purge gas, if the seal fails, atmosphere can infiltrate into the degasser volume (the housing 211), which would then permeate across the membrane of the degasser (the tube 120) since the partial pressure of atmospheric products in the precursors is low, thereby potentially contaminating the liquid precursor in the liquid container 105. The purge gas prevents the contamination of the liquid precursor by diluting any potential small leaks in the degasser volume (the housing 211), which might let the atmosphere into the degas volume (the housing 211). Thus, the inert purge gas helps prevent reactive precursors from reacting with atmosphere through the membrane of the tube 120.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A degas system comprising:
a housing including a liquid inlet, a gas inlet, a liquid outlet, and a gas outlet;
a tube configured to receive a liquid including gas bubbles, wherein:
the tube includes a plurality of loops, a first end fluidly connected to the liquid inlet of the housing, and a second end fluidly connected to the liquid outlet of the housing, and
the tube is gas permeable and liquid impermeable;
a gas supply system configured to supply gas to the gas inlet of the housing; and
a first conduit and a first restricted orifice configured to fluidly connect the gas outlet of the housing to an exhaust system.

2. The degas system of claim 1, wherein the gas supply system and the first restricted orifice are configured to create a first predetermined pressure in the housing that is greater than a second predetermined pressure of an exhaust system and less than a third predetermined pressure of the gas bubbles in the liquid.

3. The degas system of claim 1, wherein the gas supply system includes:
a gas source; and
a second conduit and a second restricted orifice having an inlet fluidly connected to the gas source and an outlet fluidly connected to the gas inlet of the housing.

4. The degas system of claim 3, wherein:
the gas source supplies gas at a first predetermined pressure;
the second restricted orifice is sized to supply gas from the gas source at a predetermined flow rate; and
the first restricted orifice is configured to maintain pressure in the housing at a second predetermined pressure.

5. The degas system of claim 4, wherein:
the first predetermined pressure is in a range from 40 to 70 psig;
the second predetermined pressure in in a range from 20 to 40 Torr;
the first restricted orifice has a size in a range from 300 to 550 micrometers; and
the second restricted orifice has a size in a range from 25 to 55 micrometers.

6. The degas system of claim 1, wherein the gas supply system includes:
a gas source; and
a pressure regulator having an inlet fluidly connected to the gas source and an outlet fluidly connected to the gas inlet of the housing.

7. The degas system of claim 6, wherein:
the gas source supplies gas at a first predetermined pressure; and
the pressure regulator and the first restricted orifice are configured to maintain pressure in the housing at a second predetermined pressure.

8. The degas system of claim 4, wherein:
the first predetermined pressure is in a range from 40 to 70 psig; and
the second predetermined pressure is in a range from 20 to 40 Torr.

9. The degas system of claim 1, wherein the gas supply system includes:
a gas source;
a gas mass flow controller having an inlet fluidly connected to the gas source; and
a valve having an inlet connected to an outlet of the gas mass flow controller and an outlet fluidly connected to the gas inlet of the housing.

10. The degas system of claim 9, wherein:
the gas source supplies gas at a first predetermined pressure; and
the gas mass flow controller, the valve, and the first restricted orifice are configured to maintain pressure in the housing at a second predetermined pressure.

11. The degas system of claim 10, wherein:
the first predetermined pressure is in a range from 40 to 70 psig; and
the second predetermined pressure is in a range from 20 to 40 Torr.

12. The degas system of claim 11, wherein the first restricted orifice has a size in a range from 300 to 550 micrometers.

13. The degas system of claim 1, wherein the gas bubbles comprise an inert gas.

14. The degas system of claim 1, wherein the liquid comprises an alkoxide of silicon.

15. The degas system of claim 1, wherein the gas comprises an inert gas.

16. A liquid delivery system for a substrate processing system, comprising:
the degas system of claim 1;
a liquid container to store the liquid;
a gas source to pressurize the liquid container; and
a conduit fluidly connecting a liquid outlet of the liquid container to the liquid inlet of the housing.

17. The liquid delivery system of claim 16, further comprising:
a liquid mass flow controller including an inlet fluidly connected to the liquid outlet of the housing; and
a vaporizer fluidly connected to an outlet of the liquid mass flow controller.

18. The degas system of claim 1, wherein the gas bubbles comprise helium (He).

19. The degas system of claim 1, wherein the liquid comprises tetraethyl orthosilicate (TEOS).

20. The degas system of claim 1, wherein the gas comprises argon (Ar).

21. The degas system of claim 1, wherein the housing is sealed from atmosphere and wherein the gas prevents the liquid from reacting with the atmosphere through the tube in the event of failure of the seal.
